(19) United States
(12) Patent Application Publication
(10) Pub. No.: US 2015/0056387 A1
(43) Pub. Date: Feb. 26, 2015

(54) METHODS FOR MAKING COATED POROUS SEPARATORS AND COATED ELECTRODES FOR LITHIUM BATTERIES

(71) Applicant: GM GLOBAL TECHNOLOGY OPERATIONS LLC, Detroit, MI (US)

(72) Inventors: Gayatri Vyas Dadheech, Bloomfield Hills, MI (US); Mei Cai, Bloomfield Hills, MI (US); Li Yang, Troy, MI (US)

(21) Appl. No.: 14/462,899

(22) Filed: Aug. 19, 2014

Related U.S. Application Data
(60) Provisional application No. 61/868,346, filed on Aug. 21, 2013.

(51) Int. Cl. H01M 4/04; C23C 14/28; H01M 4/1391; C23C 14/08; H01M 4/1393; C23C 14/32; C23C 14/06

(52) U.S. Cl. CPC H01M 4/0423; C23C 14/325; C23C 14/28; C23C 14/0605; C23C 14/08; H01M 4/1393; H01M 4/1391
USPC 427/596; 204/192.38

(57) ABSTRACT

In an example of a method for coating a lithium battery component, the lithium battery component is provided. The lithium battery component is selected from the group consisting of an uncoated or untreated porous polymer membrane or an uncoated or untreated electrode including a lithium and manganese based active material. A laser arc plasma deposition process, a cathodic arc deposition process, or a pulsed laser deposition process is used to deposit a carbon nanocomposite structure, a metal oxide nanocomposite structure, or a mixed carbon and metal oxide nanocomposite structure i) on a surface of the lithium battery component, or ii) in pores of the lithium battery component, or iii) combinations of i and ii.

### CROSS-REFERENCE TO RELATED APPLICATIONS

This application claims the benefit of U.S. Patent Provisional Application Ser. No. 61/868,346, filed Aug. 21, 2013, which is incorporated by reference herein in its entirety.

### BACKGROUND

Secondary, or rechargeable, lithium-sulfur batteries or lithium ion batteries are often used in many stationary and portable devices, such as those encountered in the consumer electronic, automobile, and aerospace industries. The lithium class of batteries has gained popularity for various reasons including a relatively high energy density, a general nonappearance of any memory effect when compared to other kinds of rechargeable batteries, a relatively low internal resistance, and a low self-discharge rate when not in use. The ability of lithium batteries to undergo repeated power cycling over their useful lifetimes makes them an attractive and dependable power source.

### SUMMARY

In an example of a method for coating a lithium battery component, the lithium battery component is provided. The lithium battery component is selected from the group consisting of an uncoated or untreated porous polymer membrane or an uncoated or untreated electrode including a lithium and manganese based active material. A laser arc plasma deposition process, a cathodic arc deposition process, or a pulsed laser deposition process is used to deposit a carbon nanocomposite structure, a metal oxide nanocomposite structure, or a mixed carbon and metal oxide nanocomposite structure i) on a surface of the lithium battery component, or ii) in pores of the lithium battery component, or iii) combinations of i and ii.

### BRIEF DESCRIPTION OF THE DRAWINGS

Features and advantages of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a schematic, perspective view of an example of a lithium-sulfur battery showing a charging and discharging state, the battery including an example of the porous separator according to the present disclosure;

FIG. 2 is a cross-sectional view of an example of a coated electrode according to the present disclosure;

FIG. 3 is a schematic view of an example of a system for coating the porous separator or electrode;

FIGS. 4A through 4C are scanning electron microscope (SEM) images of an uncoated porous polymer membrane (FIG. 4A), a carbon nanocomposite structure coated porous polymer membrane (FIG. 4B), and a SnO₂ nanocomposite structure coated porous polymer membrane (FIG. 4C);

FIG. 5 is a graph illustrating the discharge capacity (mAh/g) for examples of the porous separator disclosed herein and for comparative examples; and

FIG. 6 is a graph illustrating the effect of laser arc discharges and laser frequency on the thickness of the nanocomposite structure that is formed.

### DETAILED DESCRIPTION

Lithium-sulfur batteries and other lithium ion batteries generally operate by reversibly passing lithium ions between a negative electrode (sometimes called an anode) and a positive electrode (sometimes called a cathode). The negative and positive electrodes are situated on opposite sides of a porous polymer separator soaked with an electrolyte solution that is suitable for conducting the lithium ions. Each of the electrodes is also associated with respective current collectors, which are connected by an interruptible external circuit that allows an electric current to pass between the negative and positive electrodes.

It has been found that the lithium-sulfur battery life cycle may be limited by the migration, diffusion, or shuttling of polysulfides from the sulfur cathode during the battery discharge process, through the porous polymer separator, to the anode. The Sₓ polysulfides generated at the cathode are soluble in the electrolyte, and can migrate to the anode (e.g., a lithium electrode) where they react with the anode in a parasitic fashion to generate lower-order polysulfides. These lower-order polysulfides diffuse back to the cathode and regenerate the higher forms of polysulfide. As a result, a shuttle effect takes place. This effect leads to decreased sulfur utilization, self-discharge, poor cycleability, and reduced Coulombic efficiency of the battery. It is believed that even a small amount of polysulfide at the anode can lead to parasitic loss of active lithium at the anode, which prevents reversible electrode operation and reduces the useful life of the lithium-sulfur battery.

Similarly, it has been found that the lithium ion battery containing a manganese-based cathode may suffer from manganese dissolution. For instance, a graphite anode may be poisoned by Mn⁺² or Mn⁺³ cations that dissolve from spinel LiMn₂O₄ of the cathode. For instance, the Mn⁺² cations may migrate through the battery electrolyte and porous polymer separator, and deposit onto the graphite electrode. When deposited onto the graphite, the Mn⁺² cations become Mn atoms. It has been shown that a relatively small amount (e.g., 90 ppm) of Mn atoms can poison the graphite electrode, and prevent reversible electrode operation and thus reduce the useful life of the battery. The deleterious effect of the Mn deposited at the anode is significantly enhanced during battery exposure to above-ambient temperatures (>40° C.), irrespective of whether the exposure occurs through mere storage (i.e., simple stand at open circuit voltage in some state of charge) or during battery operation (i.e., during charge, during discharge, or during charge—discharge cycling).

In some of the examples disclosed herein, the diffusive polysulfide of the lithium-sulfur battery or the diffusive manganese cations of the lithium ion battery may be reduced or prevented by incorporating a nanocomposite structure coating on a surface of and/or in pores of a porous polymer membrane. In other of the examples disclosed herein, the deleterious effects of migrating Mn⁺² (or other transition metal) cations of the lithium ion battery may be reduced or prevented by incorporating the nanocomposite structure coating on a surface of the cathode. In yet another example disclosed herein, the parasitic effect of the shuttling polysulfides of a lithium-sulfur battery may be reduced or prevented by incorporating the nanocomposite structure coating on a surface of the sulfur cathode. In any of the examples disclosed herein, the nanocomposite structure coating may be formed of carbon, a metal oxide (e.g., an aluminum oxide, an antimony oxide, a calcium oxide, a magnesium oxide, a tin oxide, a titanium oxide, a silicon oxide, a vanadium oxide, a zirconium oxide, and mixtures thereof), or a mixture of carbon and metal oxide. The nanocomposite structure coating may be a single layer, a bilayer, or a multi-layered structure with three or more layers. The nanocomposite structure coating includes pores sized to i) allow lithium ions to pass through and ii) block polysulfide ions or manganese cations from passing through. As such, the nanocomposite structure coating disclosed herein acts as a barrier that may improve the capacity and useful life of the battery.

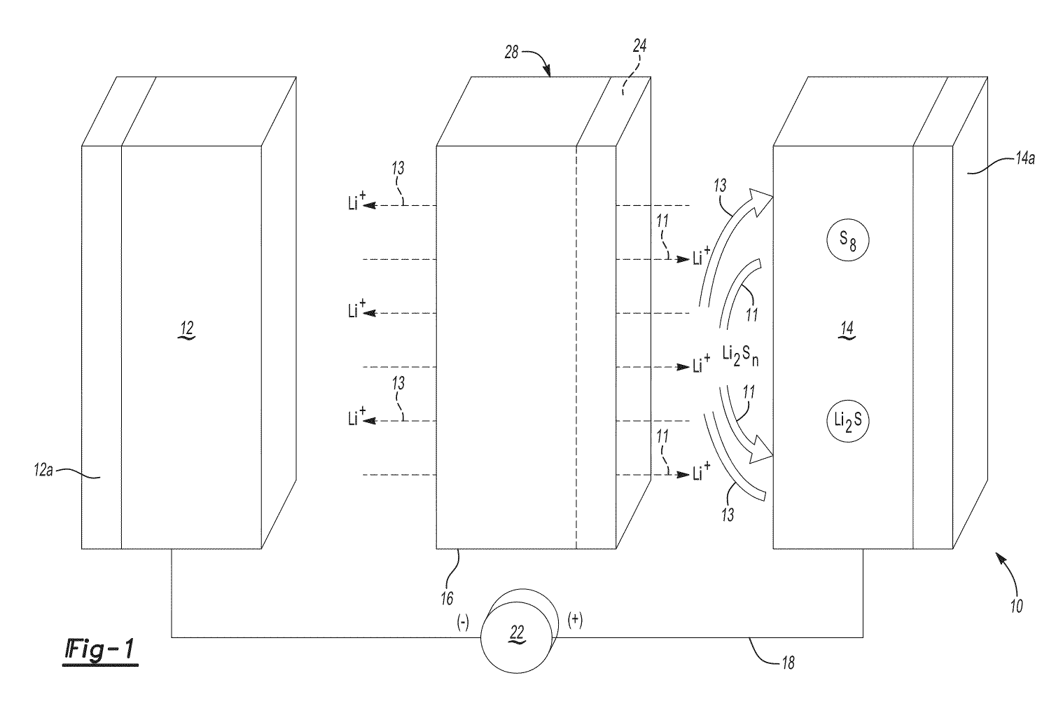

An example of a secondary lithium-sulfur battery 10 is schematically shown in FIG. 1. The battery 10 generally includes an anode 12, a cathode 14, and a porous polymer separator 28. The porous polymer separator 28 includes a porous polymer membrane 16 having the nanocomposite structure 24 formed on its surface and/or in its pores. The lithium-sulfur battery 10 also includes an interruptible external circuit 18 that connects the anode 12 and the cathode 14. Each of the anode 12, the cathode 14, and the porous polymer separator 16 are soaked in an electrolyte solution that is capable of conducting lithium ions.

The porous polymer separator 28, which operates as both an electrical insulator and a mechanical support, is sandwiched between the anode 12 and the cathode 14 to prevent physical contact between the two electrodes 12, 14 and the occurrence of a short circuit. The nanocomposite structure 24 that is formed on the surface of the membrane 16 may be positioned to face the cathode 14. The porous polymer separator 28 (i.e., the membrane 16 and the nanocomposite structure 24), in addition to providing a physical barrier between the two electrodes 12, 14, ensures passage of lithium ions (identified by the Li+) and some related anions through the electrolyte solution filling its pores. However, as discussed above, the microporous polymer separator 28 also blocks the passage of polysulfide ions due to the presence of the nanocomposite structure 24.

A negative-side current collector 12a and a positive-side current collector 14a may be positioned in contact with the anode 12 and the cathode 14, respectively, to collect and move free electrons to and from the external circuit 18.

The lithium-sulfur battery 10 may support a load device 22 that can be operatively connected to the external circuit 18. The load device 22 may be powered fully or partially by the electric current passing through the external circuit 18 when the lithium-sulfur battery 10 is discharging. While the load device 22 may be any number of known electrically-powered devices, a few specific examples of a power-consuming load device include an electric motor for a hybrid vehicle or an all-electrical vehicle, a laptop computer, a cellular phone, and a cordless power tool. The load device 22 may also, however, be a power-generating apparatus that charges the lithium-sulfur battery 10 for purposes of storing energy. For instance, the tendency of windmills and solar panels to variably and/or intermittently generate electricity often results in a need to store surplus energy for later use.

The lithium-sulfur battery 10 can include a wide range of other components that, while not depicted here, are nonetheless known to skilled artisans. For instance, the lithium-sulfur battery 10 may include a casing, gaskets, terminals, tabs, and any other desirable components or materials that may be situated between or around the anode 12 and the cathode 14 for performance-related or other practical purposes. Moreover, the size and shape of the lithium-sulfur battery 10, as well as the design and chemical make-up of its main components, may vary depending on the particular application for which it is designed. Battery-powered automobiles and hand-held consumer electronic devices, for example, are two instances where the lithium-sulfur battery 10 would most likely be designed to different size, capacity, and power-output specifications. The lithium-sulfur battery 10 may also be connected in series and/or in parallel with other similar lithium-sulfur batteries 10 to produce a greater voltage output and current (if arranged in parallel) or voltage (if arranged in series) if the load device 22 so requires.

The lithium-sulfur battery 10 can generate a beneficial electric current during battery discharge (shown by reference numeral 11 in FIG. 1). During discharge, the chemical processes in the battery 10 include delithiation from the surface of the anode 12 and incorporation of the lithium cations into alkali metal polysulfide salts (i.e., Li₂Sₓ). As such, lithium polysulfides are formed (sulfur is reduced) on the surface of the cathode 14 in sequence while the battery 10 is discharging. The chemical potential difference between the cathode 14 and the anode 12 (ranging from approximately 1.5 to 3.0 volts, depending on the exact chemical make-up of the electrodes 12, 14) drives electrons produced by the delithiation at the anode 12 through the external circuit 18 towards the cathode 14. The resulting electric current passing through the external circuit 18 can be harnessed and directed through the load device 22 until the lithium in the anode is depleted and the capacity of the lithium-sulfur battery 10 is diminished.

The lithium-sulfur battery 10 can be charged or re-powered at any time by applying an external power source to the lithium-sulfur battery 10 to reverse the electrochemical reactions that occur during battery discharge. During charging (shown at reference numeral 13 in FIG. 1), lithium plating to the anode 12 takes place and sulfur formation at the cathode 14 takes place. The connection of an external power source to the lithium-sulfur battery 10 compels the otherwise non-spontaneous oxidation of lithium at the cathode 14 to produce electrons and lithium ions. The electrons, which flow back towards the anode 12 through the external circuit 18, and the lithium ions (Li⁺), which are carried by the electrolyte across the porous polymer separator 28 back towards the anode 12, reunite at the anode 12 and replenish it with lithium for consumption during the next battery discharge cycle. The external power source that may be used to charge the lithium-sulfur battery 10 may vary depending on the size, construction, and particular end-use of the lithium-sulfur battery 10. Some suitable external power sources include a battery charger plugged into an AC wall outlet and a motor vehicle alternator.

The anode 12 may include any lithium host material that can sufficiently undergo lithium plating and stripping while a copper current collector or another suitable current collector is functioning as the negative terminal of the lithium-sulfur battery 10. The negative electrode 12 may also include a polymer binder material to structurally hold the lithium host material together. For example, the negative electrode 12 may be formed of an active material, made from graphite or a low surface area amorphous carbon, intermingled with a binder, made from polyvinylidene fluoride (PVdF), an ethylene propylene diene monomer (EPDM) rubber, sodium alginate, carboxymethyl cellulose (CMC), styrene-butadiene rubber (SBR), polyacrylic acid (PAA), polyvinyl alcohol (PVA), or another suitable binder. These materials may be mixed with a high surface area carbon, such as acetylene black, to ensure electron conduction between the current collector 12a and the active material particles of the anode 12. Graphite is widely utilized to form the negative electrode because it exhibits reversible lithium intercalation and deintercalation characteristics, is relatively non-reactive, and can store lithium in quantities that produce a relatively high energy density. Commercial forms of graphite that may be used to fabricate the anode 12 are available from, for example, Timcal Graphite & Carbon (Bodio, Switzerland), Lonza Group (Basel, Switzerland), or Superior Graphite (Chicago, Ill.). Other materials can also be used as active materials in the negative electrode, including, for example, lithium titanate, silicon, silicon alloys, etc.

The negative-side current collector 12a may be formed from copper or any other appropriate electrically conductive material known to skilled artisans.

The cathode 14 of the lithium-sulfur battery 10 may be formed from any sulfur-based active material that can sufficiently undergo lithium alloying and dealloying with aluminum or another suitable current collector functioning as the positive terminal of the lithium-sulfur battery 10. Examples of sulfur-based active materials include S₈, Li₂S₈, Li₂S₆, Li₂S₄, Li₂S₂, and Li₂S.

The cathode 14 may be encapsulated with carbon or include a high surface area carbon material, and/or may also include a polymer binder material to structurally hold the sulfur-based active material together. The polymeric binder may be made of at least one of polyvinylidene fluoride (PVdF), polyethylene oxide (PEO), an ethylene propylene diene monomer (EPDM) rubber, carboxymethyl cellulose (CMC), or any of the other binders disclosed herein.

The positive-side current collector 14a may be formed from aluminum or any other appropriate electrically conductive material known to skilled artisans.

Any appropriate electrolyte solution that can conduct lithium ions between the anode 12 and the cathode 14 may be used in the lithium-sulfur battery 10. In one example, the non-aqueous electrolyte solution may be an ether based electrolyte that is stabilized with lithium nitrite. Other non-aqueous liquid electrolyte solutions may include a lithium salt dissolved in an organic solvent or a mixture of organic solvents. Examples of lithium salts that may be dissolved in the ether to form the non-aqueous liquid electrolyte solution include LiClO₄, LiAlCl₄, Lil, LiBr, LiSCN, LiBF₄, LiB(C₆H₅)₄, LiAsF₆, LiCF₃SO₃, LiN(FSO₂)₂, LiN(CF₃SO₂)₂, LiPF₆, LITFSI, LiB(C₂O₄)₂ (LiBOB), LiBF₂(C₂O₄) (LiODFB), LiPF₄(C₂O₄) (LiFOP), LiNO₃, and mixtures thereof. The ether based solvents may be composed of cyclic ethers, such as 1,3-dioxolane, tetrahydrofuran, 2-methyltetrahydrofuran, and chain structure ethers, such as 1,2-dimethoxyethane, 1-2-diethoxyethane, ethoxymethoxyethane, tetraethylene glycol dimethyl ether (TEGDME), polyethylene glycol dimethyl ether (PEGDME), and mixtures thereof.

The porous polymer membrane 16 of the porous polymer separator 28 may be formed, e.g., from a polyolefin. The polyolefin may be a homopolymer (derived from a single monomer constituent) or a heteropolymer (derived from more than one monomer constituent), and may be either linear or branched. If a heteropolymer derived from two monomer constituents is employed, the polyolefin may assume any copolymer chain arrangement including those of a block copolymer or a random copolymer. The same holds true if the polyolefin is a heteropolymer derived from more than two monomer constituents. As examples, the polyolefin may be polyethylene (PE), polypropylene (PP), a blend of PE and PP, or multi-layered structured porous films of PE and/or PP. Commercially available porous polymer membranes include single layer polypropylene membranes, such as CELGARD 2400 and CELGARD 2500 from Celgard, LLC (Charlotte, N.C.).

It is to be understood that the porous polymer membrane 16 is uncoated or untreated. For example, the porous polymer membrane does not include any surfactant treatment thereon. The uncoated/untreated membrane adheres better to the nanocomposite structure 24 when the methods disclosed herein are used to form the nanocomposite structure 24. The improved adhesion of the nanocomposite structure 24 to the uncoated/untreated membrane is unexpected because uncoated/untreated separators have previously exhibited very poor adhesion to coatings. In attempts to improve the adhesion, surfactant coated separators have been used. However, surfactant coated separators have led to dissolution of the surfactant group and decreased battery performance. The methods disclosed herein provide quick and localized heating during deposition via the laser, which is believed to contribute to the improved adhesion without a surfactant treatment.

In another example, the membrane 16 of the porous polymer separator 28 may be formed from another polymer chosen from polyethylene terephthalate (PET), polyvinylidene fluoride (PVdF), polyamides (Nylons), polyurethanes, polycarbonates, polyesters, polyetheretherketones (PEEK), polyethersulfones (PES), polyimides (PI), polyamide-imides, polyethers, polyoxymethylene (e.g., acetal), polybutylene terephthalate, polyethylenenaphthenate, polybutene, polyolefin copolymers, acrylonitrile-butadiene styrene copolymers (ABS), polystyrene copolymers, polymethylmethacrylate (PMMA), polyvinyl chloride (PVC), polysiloxane polymers (such as polydimethylsiloxane (PDMS)), polybenzimidazole (PBI), polybenzoxazole (PBO), polyphenylenes (e.g., PARMAX™ (Mississippi Polymer Technologies, Inc., Bay Saint Louis, Miss.)), polyarylene ether ketones, polyperfluorocyclobutanes, polytetrafluoroethylene (PTFE), polyvinylidene fluoride copolymers and terpolymers, polyvinylidene chloride, polyvinylfluoride, liquid crystalline polymers (e.g., VECTRAN™ (Hoechst AG, Germany) and ZENITE® (DuPont, Wilmington, Del.)), polyaramides, polyphenylene oxide, and/or combinations thereof. It is believed that another example of a liquid crystalline polymer that may be used for the membrane 16 of the separator 28 is poly(p-hydroxybenzoic acid). In yet another example, the membrane 16 of the porous polymer separator 18 may be chosen from a combination of the polyolefin (such as PE and/or PP) and one or more of the polymers for the membrane 16 listed above.

The porous polymer membrane 16 may be a single layer or may be a multi-layer (e.g., bilayer, trilayer, etc.) laminate fabricated from either a dry or wet process. In some instances, the membrane 16 may include fibrous layer(s) to impart appropriate structural and porosity characteristics.

As mentioned above, the nanocomposite structure 24 is a carbon nanocomposite structure, a metal oxide nanocomposite structure, or a mixed carbon and metal oxide nanocomposite structure. The metal oxide may be an aluminum oxide, an antimony oxide, a calcium oxide, a magnesium oxide, a tin oxide, a titanium oxide (e.g., TiO₂ or Ti₄O₇), a silicon oxide, a tungsten oxide (e.g., WO₃) a vanadium oxide, a zirconium oxide, and mixtures thereof. In the example shown in FIG. 1, the nanocomposite structure 24 is formed on the porous polymer membrane 16. It is to be understood that the nanocomposite structure 24 may be formed on the surface of the fibers of the porous polymer membrane 16 and/or may penetrate (e.g., disperse within) the pores of the porous polymer membrane 16. While the nanocomposite structure 24 may fill the pores of the membrane 16, the nanocomposite structure 24 itself is lithium conducting and includes pores which are small enough to block polysulfide ions from moving therethrough, and are large enough to allow lithium cations to move therethrough. The nanocomposite structure 24 has a thickness of 2 μm or less (e.g., down to about 1 nm). In other examples, the thickness is 100 nm or less, or 50 nm or less. Examples of how the nanocomposite structure 24 is formed will be discussed further in reference to FIG. 3.

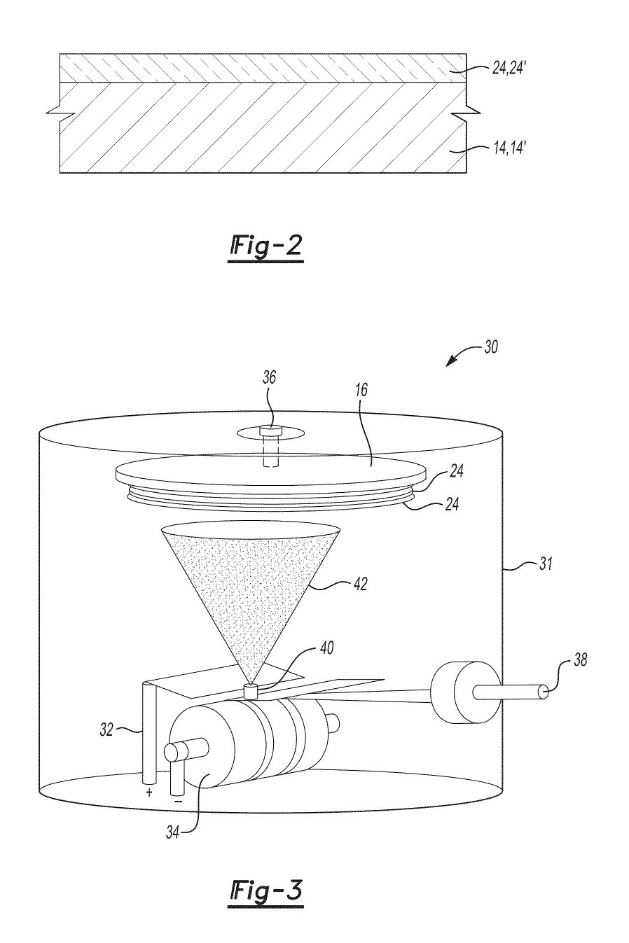

FIG. 1 illustrates a lithium-sulfur battery 10 with the nanocomposite structure 24 formed on the porous polymer membrane 16. In this example battery 10, the nanocomposite structure 24 may be formed on the positive electrode 14 instead of on the porous polymer membrane 16. The nanocomposite structure 24 may be formed on a surface of the positive electrode 14 that is to face the porous polymer membrane 16 in the battery 10, or the positive electrode 14 may be completely surrounded by the nanocomposite structure 24. Furthermore, as noted above, a lithium ion battery (not shown) including a manganese-based electrode may also benefit from the nanocomposite structure disclosed herein being deposited on the positive electrode. An example of the nanocomposite structure 24 on a positive electrode 14 for a lithium-sulfur battery 10 and a nanocomposite structure 24′ coated on a positive electrode 14′ for a lithium ion battery is shown in FIG. 2.

In this example, the positive electrode 14 may include any sulfur-based active material, high surface area carbon material, and polymer binder material as previously described. Also in this example, the positive electrode 14′ may include an active material intermingled with a polymeric binder and mixed with a high surface area carbon material, such as acetylene black. The active material in this positive electrode 14′ may be made of at least one of spinel lithium manganese oxide (LiMn₂O₄), a nickel-manganese oxide spinel [Li(Ni_{0.5}Mn_{1.5})O₂], a layered nickel-manganese-cobalt oxide [Li(NiₓMn_{y}Co_{z})O₄ or Li(NiₓMn_{y}Co_{z})O₂], lithium cobalt oxide (LiCoO₂), LiNiO₂, lithium iron phosphate (LiFePO₄), lithium iron fluorophosphate (Li₂FePO₄F), Li₂MSiO₄ (M=any ratio of Co, Fe and/or Mn), a lithium rich layer-structure cathode, such as xLi₂MnO₃-(1-x)LiMO₂ (M is composed of any ratio of Ni, Mn and/or Co), or HE-NMC (high efficiency Nickel-Manganese-Cobalt) cathodes. Still other suitable active materials include LiNiₓM₁₋ₓO₂(M is composed of any ratio of Al, Co, and/or Mg, and thus one example is lithium nickel-cobalt oxide (LiNiₓCo₁₋ₓO₂)), aluminum stabilized lithium manganese oxide spinel (LiₓMn₂₋ₓAl_{y}O₄), and lithium vanadium oxide (LiV₂O₅).

The nanocomposite structure 24 or 24′ in this example may be deposited on the surface of the positive electrode 14 or 14′. It is to be understood that the materials and thickness of the nanocomposite structure 24′ is similar to that of the nanocomposite structure 24.

The nanocomposite structure 24 or 24′ may be formed using a laser arc plasma deposition process, a cathodic arc deposition process, or a pulsed laser deposition process. These processes can be tuned to utilize relatively low temperatures (ranging from about 30° C. to about 70° C.), and thus do not deleteriously affect the membrane 16 or the electrode 14, 14′. It is believed that better adhesion between the membrane 16 or electrode 14, 14′ and the nanocomposite structure 24, 24′ may also be obtained using these particular deposition processes. Specifically, due at least in part to the speed and precision at which local heat is applied during the deposition process, improved adhesion of the nanocomposite structure 24, 24′ to the membrane 16 or electrode 14, 14′ is achieved. In an example, the local heat is applied quickly, for a time ranging from about 1 ns to about 5 fs. As a result, it has been found that untreated and/or uncoated base materials (e.g., membrane 16 or electrode 14′) may be used in the examples disclosed herein.

Since desirable adhesion between the structure 24, 24′ and the membrane 16 or electrode 14′ is obtained without pre-treating or pre-coating the membrane 16 or electrode 14′, the examples of the method disclosed herein exclude pre-treatment steps. This advantageously simplifies the processes disclosed herein, especially when compared to traditional processes, such as sol-gel processes that may require the membrane 16 or electrode 14′ to be treated or coated in order to obtain desirable adhesion with subsequently formed layers. In addition, the processes disclosed herein avoid the complications and limitations involved with high temperature processes, such as Magnetron sputter deposition and chemical vapor deposition (CVD), etc.

FIG. 3 schematically illustrates an example of the system 30 used in laser arc plasma deposition. A substrate holder 36 holds the membrane 16 or electrode 14′ (not shown in FIG. 3) in place within a vacuum chamber 31 (having a pressure of about 10⁻⁴ Pa). In general, an electric arc is used to vaporize material 42 from a cathode target 34 (which is operatively connected to an anode 32). The vaporized material 42 (e.g., carbon and/or metal oxide) then condenses on the membrane 16 or electrode 14′. In the example shown in FIG. 3, a pulsing and oscillating laser beam 38 strikes the surface of the cathode target 34 with a high current, forming a cathode spot. The cathode target 34 may be a carbon target (e.g., a graphite target) or a metal oxide target (e.g., aluminum oxide, antimony oxide, calcium oxide, magnesium oxide, tin oxide, titanium oxide, silicon oxide, vanadium oxide, and zirconium oxide). At the cathode spot, plasma is ignited (reference numeral 40), which generates a jet of vaporized material 42 of carbon and/or metal oxide which forms the nanocomposite structure 24, 24′ on the membrane 16 or electrode 14′. The cathode spot is active for a short period of time, and then it self-extinguishes and re-ignites in a new area close to the previous spot. This causes the apparent motion of the arc.

In an example system 30, the chamber 31 is a Laser-Arc Module (LAM) vacuum chamber, and the laser beam 38 is produced using a pulsed solid-state Nd:YAG laser (wavelength 1.06 μm, pulse length 150 ns, 10 kHz repetition rate, average pulse power density 15 mJ cm⁻²). The system 30 may also include a pulsed power supply (peak current 2 kA, pulse length 100 μs, repetition rate 1.8 kHz, average current 260 A) and a software/hardware controller. In an example, the chamber 31 houses a cylindrical (e.g., 160 mm diameter, up to 500 mm length) graphite (which functions as the cathode 34) and metal oxide target and a rod-shaped anode 32 for the arc discharge. The cathode 34 and anode 32 may be externally connected to a charged capacitor bank in the pulse power supply.

In an example, the laser pulses aim through a window into the LAM chamber 31 and focus onto the surface of the graphite cylinder target 34. The 150 ns laser pulse generates a rapidly expanding carbon plasma plume, which in turn ignites a 150 μs vacuum arc discharge pulse between the graphite target (cathode 34) and an anode 32. The vacuum arc discharge is the main energy source to evaporate the graphite. The pulse forming components of the power supply are designed to adjust the maximal arc current, timing and pulse shape. It is to be understood that a combination of a rotating target 34 with a linear scan of the laser pulse (arc location) along the length of the target 34 ensures very uniform target erosion and film deposition. A single laser can be used to ignite several arc sources for boosting deposition rates for wear coating deposition.

The carbon and/or metal oxide thin films may be reproducibly deposited over a wide thickness range from a few nanometers to a few micrometers. As such, these deposition techniques also enable control over the thickness of the nanocomposite structure 24, 24′. In an example, the thickness is less than 2 μm. Film thickness control may be accomplished by adjusting the number of ignited arc discharges (i.e., discharge pulses). In an example, the thickness may be decreased by lowering the plasma laser arc discharge pulses. Film thickness control may also be accomplished by adjusting the processing time. Generally, longer processing times results in thicker films.

To further illustrate the present disclosure, examples are given herein. It is to be understood that these examples are provided for illustrative purposes and are not to be construed as limiting the scope of the present disclosure.

### Example 1

Porous separators were formed according to an example of the method disclosed herein. Using laser arc plasma deposition (i.e., a plasma deposition process involving a laser arc), a carbon nanocomposite structure was formed on a CELGARD 2400 separator (Example 5), and a SnO₂ nanocomposite structure was formed on a CELGARD 2400 separator (Example 6). The CELGARD 2400 separator is an uncoated single layer polypropylene separator. Each of the nanocomposite structures in Examples 5 and 6 had a thickness of about 50 nm.

Comparative porous separators were also used. The CELGARD 2400 separator without any coating was used as Example 1. A surfactant treated separator (i.e., CELGARD 3501) was also used in some of the comparative examples. Example 2 included a V₂O₅ coating on the CELGARD 3501 separator. The V₂O₅ coating was prepared via a sol-gel method. An attempt was made to coat the CELGARD 2400 separator with a sol-gel prepared V₂O₅ coating, but the V₂O₅ coating did not adhere. Other comparative examples included a SnO₂ nanocomposite structure formed on the CELGARD 3501 separator using laser arc plasma deposition (Example 3) and a carbon nanocomposite structure formed on the CELGARD 3501 separator using laser arc plasma deposition (Example 4).

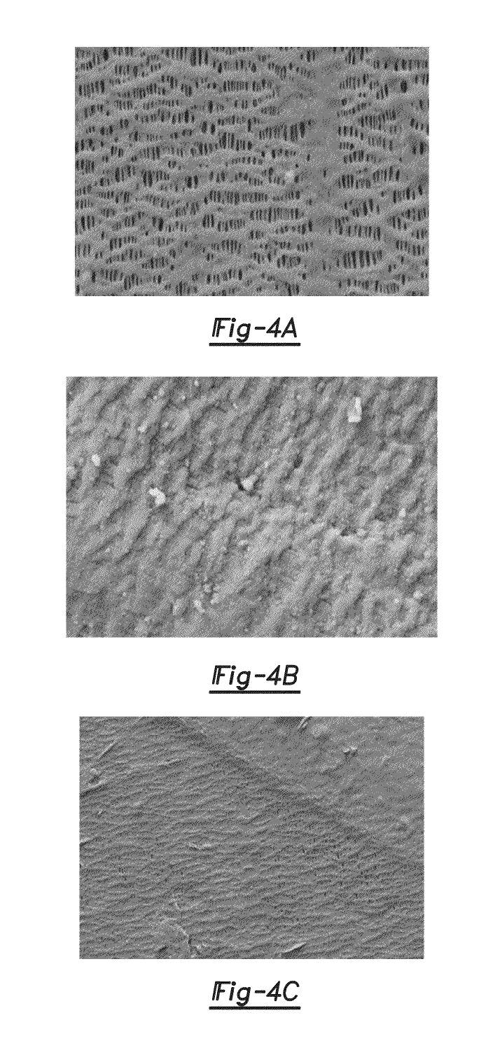

FIG. 4A is a scanning electron micrograph (SEM) image of Example 1 (i.e., the comparative example of the bare CELGARD 2400 separator), FIG. 4B is a SEM image of Example 5 (i.e., the carbon nanocomposite structure formed on the CELGARD 2400 separator), and FIG. 4C is a SEM image of Example 6 (i.e., the SnO₂ nanocomposite structure formed on the CELGARD 2400 separator). As illustrated, the carbon and metal oxide adhere to the bare membrane and form a thin nanocomposite structure thereon.

The separators (Examples 5 and 6) and the comparative separators (Comparative Examples 1-4) were assembled into respective coin cells (i.e., half cells). The coin cells were composed of a lithium metal anode, one of the examples as the porous separator, and a sulfur cathode. The coin cells were assembled in an argon-filled glove box. The electrolyte was LiTFSI salt in dioxolane/1,2-dimethoxyethane (DIOX:DME) plus 2 wt. % LiNO₃. Galvanostatic charge and discharge cycle tests were carried out at 25° C. between 2.75 V and 1.5 V.

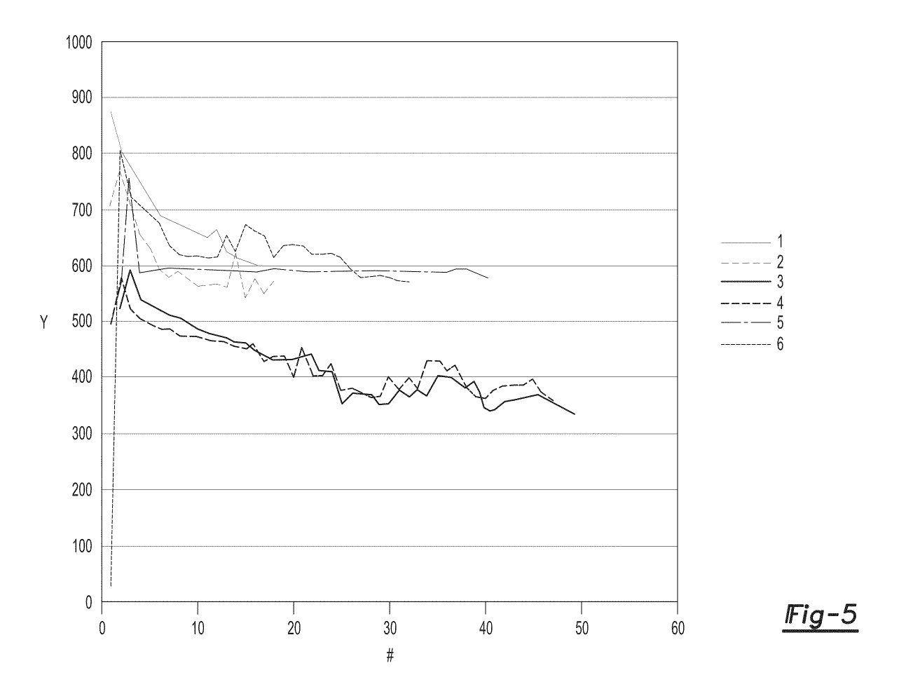

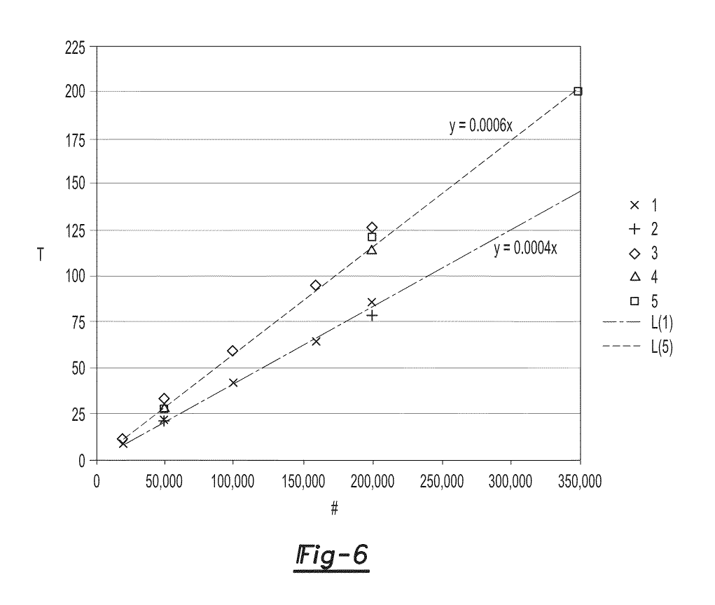

FIG. 5 illustrates the discharge curves for each of the example separators (5 and 6) and comparative example separators (1-4). As illustrated, the carbon and metal oxide nanocomposite structures coated on the bare polypropylene membranes illustrated the best discharge capacity (Y in FIG. 5, mAh/g) with the longest cycle time (# in FIG. 5). It is believed that the cycle time and capacity may be increased even further if a mixed carbon and metal oxide nanocomposite structure were used.

### Example 2

Experiments were performed to determine the deposited film thickness and film thickness uniformity as a function of the number of laser pulses/arc discharges in the range from 20,000 to 200,000 pulses as well as the repetition rate (500 Hz, 1 kHz, and 1500 Hz) of these discharges. Silicon wafers were rotated in front of a graphite cylinder during the deposition runs so that both sample sides were coated with a carbon nanocomposite structure coating. It is desirable for the thickness values to be obtained from both the front and backsides of the samples.

During these experiments, the arc discharge power supply had to be repaired. Samples 1 and 2 were prepared with the original discharge power supply and Samples 3-5 were prepared after a new controller component was installed. After the installation of the new controller component, the thickness data per number of arc discharges remained within 10%.

The laser frequency used to create Sample 1 was 500 Hz, the laser frequency used to create Sample 2 was 1 kHz, the laser frequency used to create Sample 3 was 500 Hz, the laser frequency used to create Sample 4 was 1 kHz, and the laser frequency used to create Sample 5 was 1500 Hz.

The thicknesses were determined using contact profilometry as a direct measurement on coated silicon wafers, as well as a spectroscopic method that measures material removal per area and requires mass density values to calculate thickness for a material.

The results of the film thickness measurements are shown in FIG. 6. The Y axis is the thickness (T) in nanometers, and the X-axis is the number of vacuum arc discharges. The linear extrapolations of Samples 1 and 5 are also shown. At a pulse frequency of 500 Hz, the double-sided deposition rate of 4 nm per 10,000 pulses translates to a deposition rate of 12 nm/min. This corresponds to a direct deposition rate of at least 24 nm/min at 500 Hz and 48 nm/min at 1 kHz operation. These results indicate that laser-arc technology is capable of reproducibly depositing the targeted thickness range, which in some instances ranges from about 30 nm to about 50 nm. Reproducible results were seen for thicknesses of less than 10 nm.

As illustrated in FIG. 6, the thickness of the nanocomposite structure coating may be controlled by adjusting the laser pulses/arc discharges. Also as illustrated, the thickness may increase linearly with increasing laser pulses/arc discharges.

It is to be understood that the ranges provided herein include the stated range and any value or sub-range within the stated range. For example, a range of 50 nm or less should be interpreted to include not only the explicitly recited limits of 50 nm or less, but also to include individual values, such as 25 nm, 38 nm, 10.5 nm, etc., and sub-ranges, such as from about 1 nm to about 49 nm; from about 5 nm to about 40 nm, etc. Furthermore, when “about” is utilized to describe a value, this is meant to encompass minor variations (up to +/−5%) from the stated value.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

In describing and claiming the examples disclosed herein, the singular forms “a”, “an”, and “the” include plural referents unless the context clearly dictates otherwise.

While several examples have been described in detail, it will be apparent to those skilled in the art that the disclosed examples may be modified. Therefore, the foregoing description is to be considered non-limiting.

What is claimed is:

1. A method for coating a lithium battery component, the method comprising:
providing the lithium battery component, the lithium battery component being selected from the group consisting of an uncoated or untreated porous polymer membrane or an uncoated or untreated electrode including a lithium and manganese based active material or a sulfur based active material; and
using a laser arc plasma deposition process, a cathodic arc deposition process, or a pulsed laser deposition process, depositing a carbon nanocomposite structure, a metal oxide nanocomposite structure, or a mixed carbon and metal oxide nanocomposite structure i) on a surface of the lithium battery component, or ii) in pores of the lithium battery component, or iii) combinations of i and ii.

2. The method as defined in claim 1, excluding pre-treating the uncoated or untreated porous polymer membrane or the uncoated or untreated electrode.

3. The method as defined in claim 2 wherein the carbon nanocomposite structure, the metal oxide nanocomposite structure, or the mixed carbon and metal oxide nanocomposite structure is deposited directly on the uncoated or untreated porous polymer membrane or the uncoated or untreated electrode.

4. The method as defined in claim 1, further comprising controlling a thickness of the carbon nanocomposite structure, the metal oxide nanocomposite structure, or the mixed carbon and metal oxide nanocomposite structure to 2 μm or less.

5. The method as defined in claim 4 wherein controlling the thickness is accomplished by adjusting a number of laser arc discharge pulses.

6. The method as defined in claim 4 wherein controlling the thickness is accomplished by adjusting a frequency of a laser used in the laser arc plasma deposition process, the cathodic arc deposition process, or the pulsed laser deposition process.

7. The method as defined in claim 1 wherein a temperature of the laser arc plasma deposition process, the cathodic arc deposition process, or the pulsed laser deposition process ranges from about 30° C. to about 70° C.

8. The method as defined in claim 1 wherein a graphite target is used in the laser arc plasma deposition process, the cathodic arc deposition process, or the pulsed laser deposition process to deposit the carbon nanocomposite structure.

9. The method as defined in claim 1 wherein a metal oxide target is used in the laser arc plasma deposition process, the cathodic arc deposition process, or the pulsed laser deposition process to deposit the metal oxide nanocomposite structure, wherein the metal oxide target is selected from the group consisting of aluminum oxide, antimony oxide, calcium oxide, magnesium oxide, tin oxide, titanium oxide, silicon oxide, vanadium oxide, and zirconium oxide.
